(19) United States
(12) Patent Application Publication
(10) Pub. No.: US 2022/0285199 A1
(43) Pub. Date: Sep. 8, 2022

(54) PROTECTIVE FILM FOR BACK-GRINDING WAFER

(71) Applicant: MING KUN TECHNOLOGIES CO., LTD., Taichung City (TW)

(72) Inventors: Kuo-Hsien Wang, Taichung City (TW); Chun-Teng Wang, Taichung City (TW)

(21) Appl. No.: 17/325,066

(22) Filed: May 19, 2021

(30) Foreign Application Priority Data
Mar. 8, 2021 (TW) 110108189

(51) Int. Cl. H01L 21/683; C09J 7/24

(52) U.S. Cl. CPC H01L 21/6836; C09J 7/24; H01L 2221/68331

(57) ABSTRACT

A protective film for back-grinding wafers primarily includes a base layer and a multi-film structure. The multi-film structure at least includes two TPU films, wherein the one (HPTU film) having a higher Vicat softening temperatures and/or heat deflection temperature than the other (LPTU film) contacts the base layer. The protective film optionally includes an adhesive film on one side of the LTPU film. The multi-film structure may include one or more TPU films between the HPTU and the LPTU films.

### BACKGROUND OF THE INVENTION

### 1. Field of the Invention

The present invention relates to a protective film for wafers which is particularly applied in the back-grinding process. The present invention also relates a method for manufacturing the protective film.

### 2. Description of Related Art

In the semiconductor manufacturing process, the wafers have to be thinned by back-grinding prior to packaging or dicing. To prevent bumps and circuit lines formed on the wafers from cracking, the protective tapes are provided to cover the wafers and peeled after back-grinding.

The UV curable pressure sensitive adhesive (PSA) tape is the most popular for protecting the wafers, and can be peeled after back-grinding by radiating with UV light. The UV curable adhesive tape mainly includes a base layer, a soft layer and an adhesive layer. The base layer is usually made from polyolefine (PO), polyethylene terephthalate (PET) or ethylene vinyl acetate (EVA). The soft layer made from an elastic material, for example, polyethylene (PE) and polystyrene (PS), can cover the wafer surfaces with a thickness. The adhesive layer is usually made from poly(acrylic acid), for example, poly(methyl methacrylate) (PMMA), and contains additives such as curing agents, UV initiators, inhibitors and cross-linking agents.

The thermoplastic polyurethane (TPU) is an industrial material generally used as rubber or membranes. U.S. Pat. No. 8,476,740 disclosed a sheet for protecting surface of semiconductor wafer. The sheet includes a base layer, a resin layer A and a resin layer B, wherein at least one resin layer A is disposed between the base layer and resin layer B. In order to promote peelability of the sheet, the resin layer B has a higher elastic modulus than the resin A. Though the TPU is mentioned for the resin layer B but obviously not a preferred option.

Taiwan Utility Model Patent No. 598518 disclosed a protective sheet of wafers in which a single layer of TPU is used as a soft layer. However, operating conditions of the process are complicated and difficult to control. In addition, the TPU provided in this patent is possibly unable to support the wafer during the back-grinding process at a normal operating temperature of 80° C. to 100° C.

The present invention therefore provides an improved protective film for back-grinding wafers.

### SUMMARY OF THE INVENTION

The present invention is to provide a protective film for wafers so that the wafers can be covered well during the back-grinding process and the protective film can be easily peeled after processing.

The protective film for back-grinding wafers comprises a base layer and a multi-film structure. The multi-film structure comprises two thermoplastic polyurethane (TPU) films wherein one (HTPU film) having a higher Vicat softening temperature (and/or a heat deflection temperature) than the other (LTPU film) contacts with the base layer and the LTPU film is formed on the HTPU film. The LTPU film preferably has a Shore A hardness ranging from 60A to 75A.

The base layer can be made from polyolefin (PO), polyethylene terephthalate (PET) or other materials.

The HTPU film has a heat deflection temperature ranging from 100° C. to 140° C., and preferably from 110° C. to 120° C., and a Vicat softening temperature ranging from 100° C. to 150° C., and preferably from 110° C. to 120° C.

The LTPU film has a heat deflection temperature ranging from 60° C. to 90° C., and preferably from 70° C. to 80° C., and a Vicat softening temperature ranging from 70° C. to 100° C., and preferably from 80° C. to 90° C.

Preferably, the LTPU film has a thickness of 50 μm to 250 μm and the HTPU film has a thickness of 500 μm to 260 μm, which can be adjusted according to surface heights of the wafers.

The protective film for back-grinding wafers can further comprise a TPU film having a Vicat softening temperature (and/or a heat deflection temperature) not higher than those of the HTPU film and not lower than those of the LTPU film.

The protective film for back-grinding wafers can further comprise an adhesive layer formed on the LTPU film, and preferably a UV curable pressure sensitive adhesive (PSA), for example, poly(methyl methacrylate) (PMMA). The UV curable PSA comprising PMMA and epoxy is more preferred. The adhesive layer has a thickness of 40 μm to 90 μm.

The adhesive can optionally include additives, for example, curing agents, UV initiators, inhibitors and so on. The preferred curing agents are 2,4-diisocyanato-1-methyl-benzene (TDI) and hexamethylene diisocyanate (HDI) with a content of 0.5% to 3% in the adhesive, and preferably of 1% to 2%. The preferred UV initiator is benzophenone with a content of 0.5% to 3% in the adhesive, and preferably of 1% to 2%. The preferred inhibitors are acetate and benzoic acid with a content of 0.03% to 2% in the adhesive, and preferably of 0.05% to 1%.

The protective film for back-grinding wafers can further comprise a releasing layer on the surface of the LTPU film or the adhesive layer. The releasing layer is usually made from polyethylene terephthalate (PET) or other materials.

The present invention also provides a method for manufacturing the protective film for back-grinding wafers with a lower cost and simpler procedures. The method for manufacturing the protective film for back-grinding wafers comprises steps of: forming a multi-film structure comprising an HTPU film and an LTPU film wherein the LTPU film has a Vicat softening temperature (and/or a heat deflection temperature) lower than the HTPU film; and forming a base layer on the surface of the HTPU film of the multi-film structure. The multi-film structure is formed through a process, for example, co-extruding, attaching and spreading, among which the co-extruding process is preferred. Temperatures of the extruders are set according to the Vicat softening temperature and the heat deflection temperature of the TPU materials. The extruder for the HTPU film is preferably set at 120° C. to 200° C., and more preferably at 130° C. to 180° C. The extruder for the LTPU film is preferably set at 100° C. to 180° C., and more preferably at 110° C. to 160° C.

The manufacturing method may further comprise a step of: forming a TPU film between the HTPU film and the LTPU film, which has a Vicat softening temperature (and/or a heat deflection temperature) not higher than that of the HTPU film and not lower than that of the LTPU film.

The manufacturing method may further comprise a step of: spreading an adhesive on the surface of the LTPU film to form an adhesive layer.

The manufacturing method may further comprise a step of: forming a releasing layer on the surface of the multi-film structure or the adhesive.

The base layer, the HTPU film, the LTPU film, the adhesive layer and the releasing layer are defined as the above.

### BRIEF DESCRIPTION OF THE DRAWINGS

FIG. 1 shows the protective film of this invention including four layers/films.

FIG. 2 shows the protective film of this invention including five layers/films.

FIG. 3 shows the protective film of this invention including three layers/films.

### DETAILED DESCRIPTION OF THE PREFERRED EMBODIMENTS

To illustrate the protective film for back-grinding wafers of this invention, the preferred embodiments are described but not to limit this invention.

In this description, Vicat softening temperatures are measured according to ASTM D1525, heat deflection temperatures are measured according to ASTM 648, Shore A hardness is measured according to ASTM D2240-05 and adhesive strength is measured according to JIS Z0237 8.

The protective film for back-grinding wafers of this invention is characterized by the multi-film structure including at least two thermoplastic polyurethane (TPU) films with different heat deflection temperatures and Vicat softening temperatures. The TPU film having a heat deflection temperature and a Vicat softening temperature higher than those of the other is referred to as the HTPU film and the other is referred to as the LTPU film. The HTPU film has low adhesive strength or even non-adhesive. Between the TPU films of the multi-film structure, there is perhaps no obvious interface because of similar properties thereof. In the multi-film structure, the TPU film having a higher Vicat softening temperature (and/or a higher heat deflection temperature) is closer to the base layer. When being attached to a wafer at an operation temperature, the TPU film having a lower Vicat softening temperature (and/or heat deflection temperature) covers the wafer and is deformed by the shape of bumps and circuit lines thereon so as to protect the wafer during the back-grinding process. The TPU film having a higher Vicat softening temperature (and/or heat deflection temperature) retains sufficient strength to support the protective film. These TPU films are made from very similar materials and therefore perform good adjustability with the shape of the wafer.

The TPU films can be supplied from commercial products or produced from reactions. The commercial products can be in the form of particles or films which may be further processed with different equipment. The reactions usually include reactants such as isocyanate, polyol and additives.

The base layer can be made from any materials, for example, polyolefine (PO), poly ester (PE), polyethylene terephthalate (PET) and ethylene vinyl acetate (EVA), among which PET is used in the following examples.

The adhesive can be made from any materials for the back-grinding process of wafers, for example, the UV curable pressure sensitive adhesive (PSA) and the heat curable PSA. In the following examples, the UV curable PMMA adhesive with epoxy is used and referred to as E-g-PMMA. For E-g-PMMA, “g” indicates a ratio of epoxy to PMMA and ranges from 5 to 20, for example, 5, 10 and 15. E-g-PMMA may further include other additives such as curing agents, UV initiators, and inhibitors. A preferred formula of the E-g-PMMA PSA includes 2,4-diisocyanato-1-methyl-benzene (TDI, 1.5 wt %) serving as a curing agent, benzophenone (1.5 wt %) serving as a UV initiator and acetate (0.1 wt %) serving as an inhibitor.

In this invention, the LTPU film may replace the above adhesive to directly cover the wafer by adding additives therein or a means.

### EXAMPLE 1

Commercial TPU particles are used. The HTPU has a Vicat softening temperature of 100° C. and a heat deflection temperature of 100° C. The LTPU has a Vicat softening temperature of 70° C., a heat deflection temperature of 60° C. and a Shore A hardness of 70.

The HTPU particles and the LTPU particles from their respective feeders are extruded through the co-extrusion dies to be laminated and combined as a multi-film structure. The extruders for the HTPU and the LTPU are respectively set at 120° C. and 100° C. Thicknesses of the HTPU film and the LTPU film are respectively 300 μm and 50 μm. The extruded multi-film structure is cooled and rolled.

The multi-film structure is then attached to the PET base layer with the HTPU side. The PET base layer has a thickness of 80 μm.

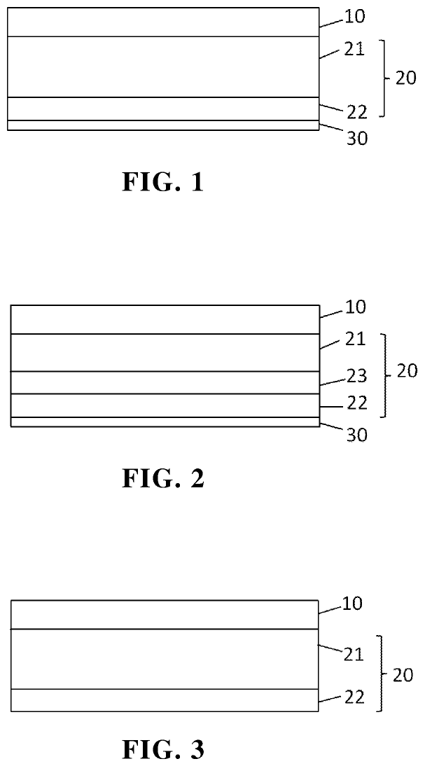

Consequently, the adhesive (E-g-PMMA) is spread on the LTPU film to obtain the protective film for back-grinding wafers. As shown in FIG. 1, the protective film includes the base layer 10, the multi-film structure 20 and the adhesive layer 30. The multi-film structure 20 includes the HTPU film 21 contacting with the base layer 10 on one side and the LTPU film 22 formed on the other side of the HTPU film 21. The Vicat softening temperature and the heat deflection temperature of the HTPU film 21 are relatively higher than those of the LTPU film 22. The adhesive layer 30 is spread on the other side of the LTPU film 22.

### EXAMPLE 2

The procedures of Example 1 are repeated except that the HTPU has a Vicat softening temperature of 110° C. and a heat deflection temperature of 100° C. and the LTPU has a Vicat softening temperature of 80° C., a heat deflection temperature of 70° C. and a Shore A hardness of 70.

The extruders for the HTPU and the LTPU are respectively set at 140° C. and 130° C.

### EXAMPLE 3

The procedures of Example 1 are repeated except that the HTPU has a Vicat softening temperature of 120° C. and a heat deflection temperature of 120° C. and the LTPU has a Vicat softening temperature of 90° C., a heat deflection temperature of 80° C. and a Shore A hardness of 70.

The extruders for the HTPU and the LTPU are respectively set at 180° C. and 160° C.

### EXAMPLE 4

Commercial TPU films are used. The HTPU has a Vicat softening temperature of 130° C., a heat deflection temperature of 130° C. and a thickness of 300 μm. The LTPU has a Vicat softening temperature of 100° C., a heat deflection temperature of 90° C., a thickness of 50 μm and a Shore A hardness of 70.

The HTPU film and the LTPU film are heated so as to be combined to form a multi-film structure which is then cooled and rolled.

The multi-film structure is then attached to the PET base layer with the HTPU side. The PET base layer has a thickness of 80 μm.

Consequently, the adhesive E-g-PMMA is spread on the LTPU film to obtain the protective film for back-grinding wafers.

### EXAMPLE 5

The procedures of Example 4 are repeated except that the HTPU has a Vicat softening temperature of 140° C. and a heat deflection temperature of 140° C. and the LTPU has a Vicat softening temperature of 80° C., a heat deflection temperature of 70° C. and a Shore A hardness of 70.

### EXAMPLE 6

The procedures of Example 4 are repeated except that the HTPU has a Vicat softening temperature of 150° C. and a heat deflection temperature of 150° C. and the LTPU has a Vicat softening temperature of 90° C., a heat deflection temperature of 80° C. and a Shore A hardness of 70.

### Test for the Protective Films

Adhesive strength of the protective films of Examples 1-6 is measured. Before being radiated with UV light, the protective films have adhesive strength ranging from 150 gf/25 mm to 220 gf/25 mm. After being radiated with UV light, the protective films have adhesive strength ranging from 15 gf/25 mm to 80 gf/25 mm. The protective films are then attached to the wafers having the same surface conditions at 80° C. As a result, the wafers are well protected during the back-grinding process and the protective films can be easily peeled without residues. In other words, the protective films perform excellent adjustability with the bumps and circuit lines on the wafer surfaces and firm combination between the base layer, the HTPU film, the LTPU film and the adhesive layer. The protective films of Examples 2-5 are better and those of Examples 2 and 3 are the best.

Particularly, a TPU film having a Vicat softening temperature (and/or a heat deflection temperature) not higher than those of the HTPU film and not lower than those of the LTPU film can be formed between the HTPU film and the LTPU film.

The multi-film structure is not restricted by the HTPU film and the LTPU film as in the above Examples. FIG. 2 shows an “MTPU” film 23 having a “middle” Vicat softening temperature ranging between the HTPU film 21 and the LTPU film 22 and formed between them.

The multi-film structure is also not restricted by only one HTPU film or only one LTPU film as in the above Examples. Optionally, there can be two or more HTPU film or LTPU film according to the required thickness.

In this invention, the above adhesive layer can be replaced with the LTPU film. As shown in FIG. 3, the protective film for back-grinding wafers includes the base layer 10 and the multi-film structure 20 including the HTPU film 21 and the LTPU film 22. The HTPU film 21 contacts with the base layer 10 and the LTPU film 22 is formed on the other side of the HTPU film 21. By adding additives therein or a means, the LTPU film 22 can well cover the wafer without a separate adhesive layer.

The effects for protecting the wafers may be influenced by various factors, for example, compositions, thickness and hardness, of the TPU films, the adhesive layer and the base layer, surface conditions of the wafers, the operating temperatures, etc. The above Examples are used to verify that the multi-film structure of TPU is feasible for protecting wafers during the back-grinding process.

1. A protective film for back-grinding wafers, the protective film comprising:
a base layer; and
a multi-film structure comprising two thermoplastic polyurethane (TPU) films, wherein one (HTPU film) having a higher Vicat softening temperature than the other (LTPU film) contacts with the base layer.

2. The protective film for back-grinding wafers of claim 1, wherein the base layer is made from polyolefin (PO) or polyethylene terephthalate (PET).

3. The protective film for back-grinding wafers of claim 1, wherein the LTPU film has a Shore A hardness ranging from 60 to 75.

4. The protective film for back-grinding wafers of claim 1, wherein the HTPU film has a heat deflection temperature ranging from 100° C. to 140° C., and the LTPU film has a heat deflection temperature ranging from 60° C. to 90° C.

5. The protective film for back-grinding wafers of claim 1, wherein the HTPU film has a Vicat softening temperature ranging from 100° C. to 150° C., and the LTPU film has a Vicat softening temperature ranging from 70° C. to 100° C.

6. The protective film for back-grinding wafers of claim 1, further comprising a TPU film having a Vicat softening temperature and a heat deflection temperature not higher than those of the HTPU film and not lower than those of the LTPU film.

7. The protective film for back-grinding wafers of claim 1, further comprising an adhesive layer formed on the LTPU film.

8. The protective film for back-grinding wafers of claim 7, wherein the adhesive layer is a layer of UV curable pressure sensitive adhesive.

9. The protective film for back-grinding wafers of claim 8, wherein the UV curable pressure sensitive adhesive comprises poly(methyl methacrylate) (PMMA) and epoxy.
